(19) United States
(12) Patent Application Publication
(10) Pub. No.: US 2024/0162353 A1
(43) Pub. Date: May 16, 2024

(54) SEMICONDUCTOR DEVICE

(71) Applicant: RENESAS ELECTRONICS CORPORATION, Tokyo (JP)

(72) Inventor: Nao NAGATA, Tokyo (JP)

(21) Appl. No.: 18/486,626

(22) Filed: Oct. 13, 2023

(30) Foreign Application Priority Data
Nov. 11, 2022 (JP) 2022-181201

(51) Int. Cl. H01L 29/861; H01L 27/06; H01L 29/32; H01L 29/739

(52) U.S. Cl. CPC H01L 29/8613; H01L 27/0664; H01L 29/32; H01L 29/7397

(57) ABSTRACT

A semiconductor device according to the present disclosure includes a semiconductor substrate having a first surface and a second surface opposite to the first surface, and a diode formed in the semiconductor substrate. The diode includes a drift layer of a first conductivity type on a side provided with the first surface, an anode layer of a second conductivity type opposite in conductivity type to the first conductivity type on the drift layer, and a trench. A bottom surface of the anode layer is located in a region deeper than a bottom surface of the trench with reference to the first surface.

### CROSS-REFERENCE TO RELATED APPLICATIONS

The disclosure of Japanese Patent Application No. 2022-181201 filed on Nov. 11, 2022 including the specification, drawings and abstract is incorporated herein by reference in its entirety.

### BACKGROUND

The present disclosure relates to a semiconductor device, and more particularly to a semiconductor device including an insulated gate bipolar transistor (IGBT).

There is disclosed a technique listed below. [Patent Document 1] Japanese Unexamined Patent Application Publication No. 2019-192743

Patent Document 1 discloses a reverse-conducting IGBT (RC-IGBT) in which an insulated gate bipolar transistor and a free wheeling diode (FWD) are integrated into one chip.

### SUMMARY

The RC-IGBT is obtained by incorporating the FWD into the IGBT chip, and has an advantage of reducing loss and downsizing of elements included in a semiconductor device. On the other hand, many problems remain in the performance of the FWD such as a recovery loss (Err) and degradation of a forward drop voltage (VF) of the FWD.

In order to suppress the loss and degradation, introduction of a local lifetime killer is considered, and introduction thereof under an anode layer is considered to be ideal.

Patent Document 1 discloses the RC-IGBT, but the anode layer is formed shallower than a trench in an FWD region. For this reason, there are concerns about an influence on the breakdown resistance and the reliability due to an increase in the electric field intensity to the bottom portion of the trench, and damage to the trench oxide film due to the introduction of the lifetime killer.

In addition to these, the FWD, which has a low-cost process, is formed in the IGBT region, which has a high-cost process. Therefore, to achieve a cost advantage, it is important to increase the power density (chip shrink) of the chip.

Other problems and novel features will be apparent from the description of the present specification and the accompanying drawings.

A semiconductor device according to the present disclosure includes a semiconductor substrate having a first surface and a second surface opposite to the first surface, and a diode formed in the semiconductor substrate. The diode includes a drift layer of a first conductivity type on a side provided with the first surface, an anode layer of a second conductivity type opposite in conductivity type to the first conductivity type on the drift layer, and a trench. A bottom surface of the anode layer is located in a region deeper than a bottom surface of the trench with reference to the first surface.

A semiconductor device according to the present disclosure includes a semiconductor substrate having a first surface and a second surface opposite to the first surface, and a diode formed in the semiconductor substrate. The diode includes a drift layer of a first conductivity type on a side provided with the first surface, an anode layer of a second conductivity type opposite in conductivity type to the first conductivity type on the drift layer, and a first trench and a second trench. A bottom surface of the anode layer is located in a region deeper than a bottom surface of the first trench with reference to the first surface. An independent voltage from a voltage applied to a trench electrode of the first trench is applied to a trench electrode of the second trench.

A semiconductor device according to the present disclosure includes a semiconductor substrate having a first surface and a second surface opposite to the first surface, and an insulated gate bipolar transistor (IGBT) and a diode formed in the semiconductor substrate. The diode includes a drift layer of a first conductivity type on a side provided with the first surface, layer of a second conductivity type opposite in conductivity type to the first conductivity type on the drift layer, and a first trench and a second trench. A bottom surface of the anode layer is located in a region deeper than a bottom surface of the first trench with reference to the first surface. An independent voltage from a voltage applied to a trench electrode of the first trench is applied to a trench electrode of the second trench. A layer of the first conductivity type is provided between the first trench and the second trench.

According to the present disclosure, it is possible to provide a semiconductor device including an RC-IGBT capable of reducing VF of a diode.

### BRIEF DESCRIPTION OF THE DRAWINGS

FIG. 1 is a configuration diagram of a semiconductor device according to a first embodiment.

FIG. 2 is a plan view of a semiconductor substrate included in the semiconductor device according to the first embodiment.

FIG. 3 is a diagram for explaining control of a lifetime killer in a diode of the semiconductor device according to the first embodiment and a comparative diode.

FIG. 4 is a diagram illustrating an impurity concentration distribution in the semiconductor device according to the first embodiment and the comparative diode.

FIG. 5 illustrates simulation results of electric field intensity distributions in the semiconductor device according to the first embodiment and the comparative diode.

FIG. 6 illustrates simulation results of VF-IF curves in the semiconductor device according to the first embodiment and the comparative diode.

FIG. 7 is a configuration diagram of a semiconductor device according to a second embodiment.

FIG. 8 is a configuration diagram of a semiconductor device according to a third embodiment.

FIGS. 9A-9F are diagrams illustrating a manufacturing flow of the semiconductor device according to the third embodiment.

FIG. 10 illustrates simulation results of the VF-IF curves and recovery waveforms in the semiconductor device according to the third embodiment and the comparative diode.

FIG. 11 is a graph illustrating trade-off curves in the semiconductor device according to the third embodiment and the comparative diode.

FIG. 12 is a configuration diagram of a semiconductor device according to a fourth embodiment.

FIG. 13 illustrates operation of the semiconductor device according to the fourth embodiment.

FIG. 14 is a configuration diagram of a semiconductor device according to a fifth embodiment.

FIG. 15 is a configuration diagram of a semiconductor device according to a sixth embodiment.

### DETAILED DESCRIPTION

Hereinbelow, embodiments of the present disclosure will be described in detail with reference to the drawings. In the specification and the drawings, the same components or corresponding components are denoted by the same reference signs, and redundant description is omitted. In the drawings, the configuration may be omitted or simplified for convenience of description. In addition, at least a part of each of the embodiments may freely be combined with each other.

A semiconductor device according to each of the embodiments may have a configuration in which a conductivity type (p type or n type) of a semiconductor substrate, a semiconductor layer, a diffusion layer (diffusion region), or the like is inverted. Therefore, in a case where one of the n type and the p type conductivity types is a first conductivity type and the other conductivity type is a second conductivity type, the first conductivity type can be the p type and the second conductivity type can be the n type, and conversely, the first conductivity type can be the n type and the second conductivity type can be the p type.

### First Embodiment

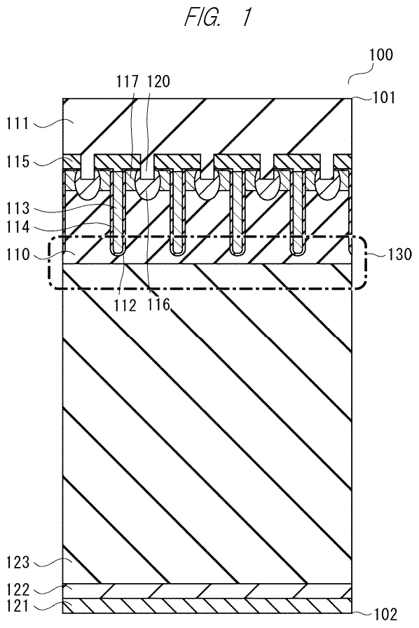

FIG. 1 illustrates a region where a diode (FWD) is formed in a semiconductor substrate included in a semiconductor device according to the present embodiment. A semiconductor substrate 100 has a first surface 101 and a second surface 102 opposite to the first surface 101 in a cross-sectional view.

On a side provided with the first surface 101 of the semiconductor substrate 100, a p type anode layer 110, an anode electrode 111, a trench 112 having a trench electrode 113 and a trench oxide film 114 therein, an interlayer insulating film 115, a p+ type body layer 116 in an IGBT, and a channel layer 117 in the IGBT are formed. The body layer 116 is provided with a contact hole 120, and the anode electrode 111 is connected to the body layer 116 via the contact hole 120. The trench 112 has a shape extending in a direction from the first surface 101 to the second surface 102, that is, in a vertical direction. The trench oxide film 114 is formed along the inner wall of the trench 112, and the trench electrode 113 is formed so as to fill the trench 112 with the trench oxide film 114 interposed between the inner wall and the trench electrode 113.

On a side provided with the second surface 102 of the semiconductor substrate 100, an n++ type cathode layer 121, an n+ type field stop layer 122, and an n− type drift layer 123 are formed. The anode layer 110 is located on the drift layer 123.

A region circled by the broken line in FIG. 1 represents a pn junction portion 130.

In the diode according to the present embodiment, the bottom surface of the anode layer 110 is located in a region deeper than the bottom surface of the trench 112 with reference to the first surface 101. In other words, the diode according to the present embodiment has a structure in which the trench 112 does not penetrate the pn junction portion 130. In the present embodiment, the anode layer formed up to a region deeper than the bottom surface of the trench is referred to as a “deep anode layer”, and is distinguished from a general anode layer.

By providing the deep anode layer 110, a region of the pn junction portion 130 near the trench 112 functions as an anode, so that a diode region formed by the pn junction expands. In addition, the trench in the region where the deep anode layer is formed improves a carrier accumulation effect in the anode layer. As a result, the forward drop voltage (VF) can be reduced.

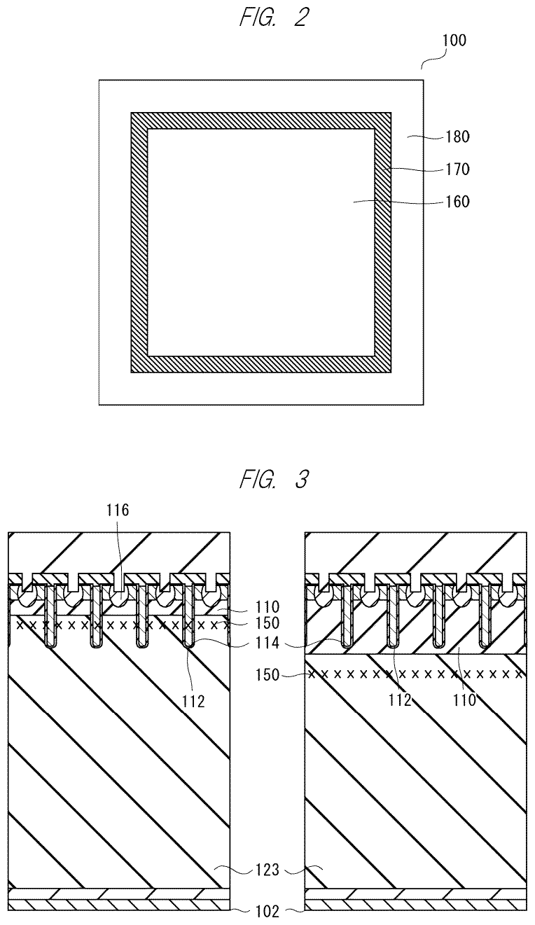

FIG. 2 is a plan view of the semiconductor substrate 100 according to the present embodiment. A reverse-conducting insulated gate bipolar transistor (RC-IGBT) according to the present embodiment includes the IGBT and the diode in an active region 160. A deactivated IGBT cell may be disposed in an active termination region 170. A peripheral region 180 is a termination region where the IGBT and the diode are not formed.

The depth (thickness) of the anode layer 110 with reference to the first surface 101 is preferably uniform at least in the active region 160 constituting the diode, and the depth is preferably the same or smaller in the active termination region 170. In a case where the depth in the active termination region 170 increases, the ability of conduction increases in the active termination region 170, so that power tends to concentrate at the off time, which causes destruction.

In addition, it is preferable to introduce a lifetime killer in order to suppress the degradation of VF and to accelerate the switching speed of the diode. Control of introduction of the lifetime killer in the diode according to the present embodiment will be described with reference to FIG. 3. The left diagram in FIG. 3 illustrates a comparative diode, and the right diagram in FIG. 3 illustrates the diode according to the present embodiment. The anode layer 110 included in the comparative diode is formed in a region shallower than the trench 112, and thus has a structure in which the trench penetrates a region where the pn junction is formed.

The lifetime killer 150 is introduced from the side provided with the second surface 102 of the semiconductor substrate 100, and a defect is formed in a desired region of the diode. The lifetime killer 150 is preferably introduced into the drift layer 123 near a region of an opposite conductivity type to that of the drift layer 123. Thus, the lifetime killer 150 is introduced under the anode layer 110.

At this time, in the comparative diode, since a defect is formed in the region where the trench 112 is formed by the lifetime killer 150, the trench oxide film 114 is damaged. In the diode according to the present embodiment, since the anode layer 110 is formed up to a region deeper than the trench 112, damage to the trench oxide film 114 is suppressed. Therefore, by providing the deep anode layer 110, control for locally introducing the lifetime killer becomes easy.

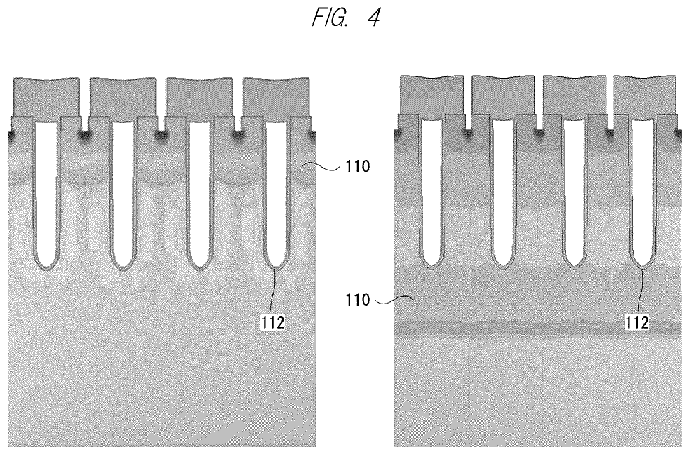

A result of comparing electric field intensity distributions of the diode according to the present embodiment and the comparative diode using a TCAD simulation will be shown. First, the structures and impurity concentrations of the diode according to the present embodiment and the comparative diode were set as illustrated in FIG. 4. The left diagram in FIG. 4 illustrates the comparative diode including the anode layer 110 formed in a region shallower than the trench 112, and the right diagram in FIG. 4 illustrates the diode according to the present embodiment including the deep anode layer 110.

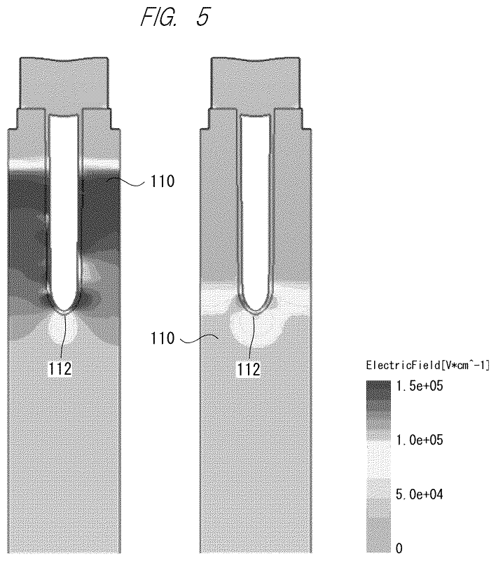

Next, simulation results of the electric field intensity distributions of the respective diodes are illustrated in FIG. 5. It can be seen that the electric field concentrates in the vicinity of the side surface of the trench 112 in the comparative diode. On the other hand, it can be seen that the diode according to the present embodiment has reduced electric field strength.

From this, it can be seen that by providing the anode layer deeper than the trench, it is possible to improve the tolerance of a reverse bias safe operation area (RBSOA) by suppressing the occurrence of dynamic avalanche, and in addition, it is possible to suppress the influence of hot carriers.

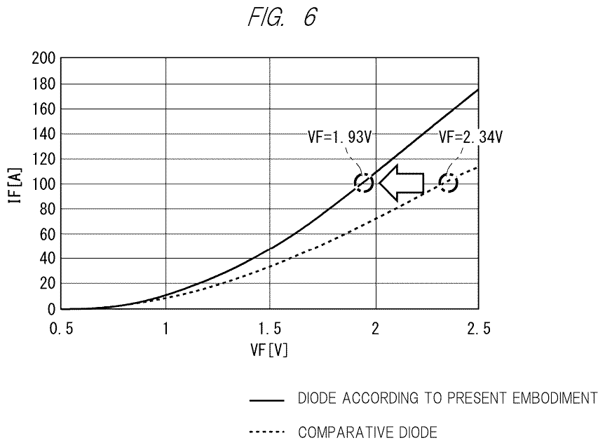

Next, simulation results of VF-IF curves of the diode according to the present embodiment and the comparison diode are illustrated in FIG. 6. FIG. 6 is a graph in which the horizontal axis represents a forward voltage and the vertical axis represents a forward current. Note that the solid line in the figure is a plotted curve of the diode according to the present embodiment, and the dotted line is a plotted curve of the comparative diode, and the same applies to the other embodiments.

When the IF is 100 A, the VF is 1.93 V in the diode according to the present embodiment and 2.34 V in the comparative diode, and thus the VF is reduced by about 17.5%. This shows that the diode according to the present embodiment has an effect of reducing the VF.

In this manner, it is possible to provide a semiconductor device including an RC-IGBT capable of reducing VF of a diode.

### Second Embodiment

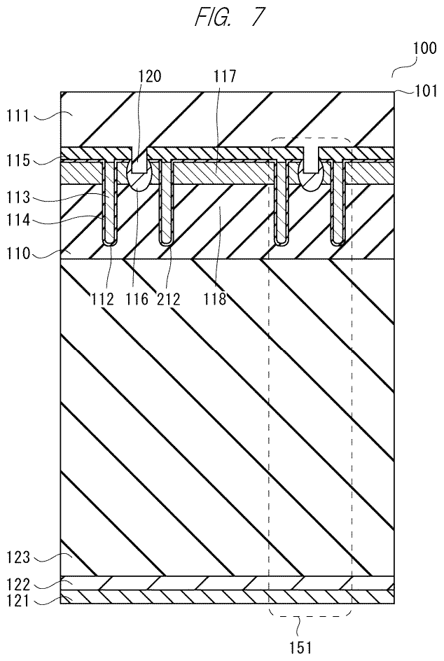

In the present embodiment, a semiconductor device obtained by advancing the first embodiment will be described. FIG. 7 illustrates a region where a diode (FWD) is formed in a semiconductor substrate included in a semiconductor device according to the present embodiment. In the diode according to the present embodiment, similarly to the first embodiment, the anode layer 110 is formed up to a region deeper than the trench 112.

In the diode according to the present embodiment, a region formed by two adjacent trenches 112 and 212 and the contact hole 120 therebetween is one unit cell, and the cell density is smaller than that of the diode according to the first embodiment. With such a configuration, the anode layer 110 has a region 118 where the contact hole 120 is not formed. In a conductive region (as an example, a region surrounded by a broken line 151) as a diode, carriers move through the contact hole 120. On the other hand, since the contact hole 120 is not formed in the region 118, the region 118 has a function of accumulating carriers, and thus the forward drop voltage (VF) can be reduced.

As a result of simulating the VF-IF curve of the diode according to the present embodiment by a similar method to that of the first embodiment, the VF of the diode according to the present embodiment when the IF is 100 A is 1.78 V. The VF is reduced by about 23.9% as compared with the comparative diode of the first embodiment. This shows that the diode according to the present embodiment has an effect of reducing the VF.

### Third Embodiment

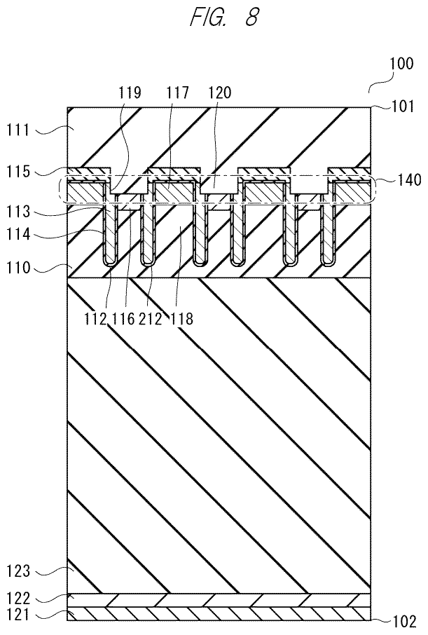

In the present embodiment, a semiconductor device obtained by advancing the first and second embodiments will be described. FIG. 8 illustrates a region where a diode (FWD) is formed in a semiconductor substrate included in a semiconductor device according to the present embodiment. In the diode according to the present embodiment, similarly to the second embodiment, the anode layer 110 is formed up to a region deeper than the trench 112, and has the region 118 where the contact hole 120 is not formed.

The diode according to the present embodiment includes a region 119 where the anode electrode 111 and the trench electrode 113 are in contact with each other by expanding the contact hole 120 to a region overlapping with the two trenches 112 and 212. With such a configuration, a share contact portion 140 is formed.

By providing the share contact portion 140, the effect of pulling out the carriers is improved, so that the recovery loss (Err) can be reduced.

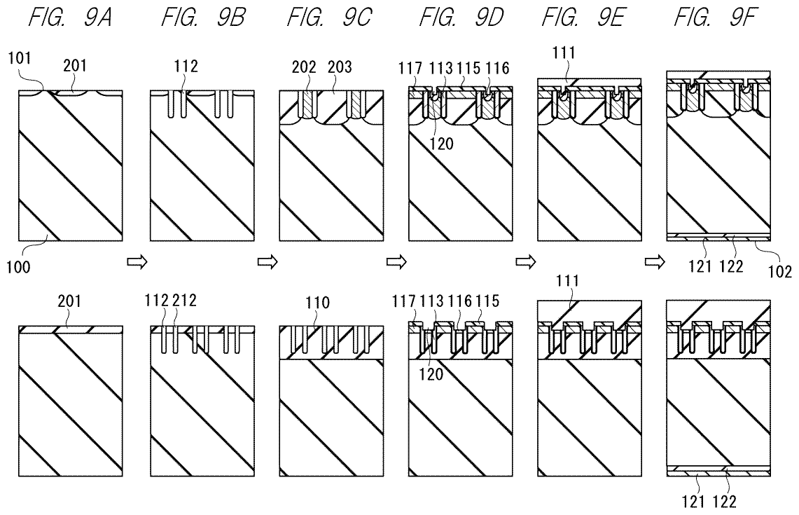

A manufacturing flow of the diode according to the present embodiment will be described with reference to FIG. 9. The upper part of FIG. 9 is a manufacturing flow of a region where the IGBT is formed, and the lower part of FIG. 9 is a manufacturing flow of a region where the diode is formed.

First, impurities are introduced into the first surface 101 of the semiconductor substrate 100 to form an impurity introduction region 201 (refer to FIG. 9A). Subsequently, the trenches 112 and 212 are formed on the first surface 101 of the semiconductor substrate 100 (refer to FIG. 9B). Subsequently, the impurity introduction region 201 is diffused to form a hole barrier layer 202 and a floating layer 203 on the IGBT side, and the anode layer 110 is formed on the diode side (refer to FIG. 9C).

Thereafter, the trench electrode 113, the interlayer insulating film 115, the body layer 116, the channel layer 117, and the contact hole 120 are formed (refer to FIG. 9D) , and the anode electrode 111 in contact with the trench electrode 113 and the body layer 116 in the contact hole 120 is formed (refer to Finally, the cathode layer 121 and the field stop FIG. 9E). layer 122 are formed on the second surface 102 of the semiconductor substrate 100 (refer to FIG. 9F).

As illustrated in FIG. 9, the diode according to the present embodiment can be formed by the same process as that of the IGBT, that is, without providing an additional process.

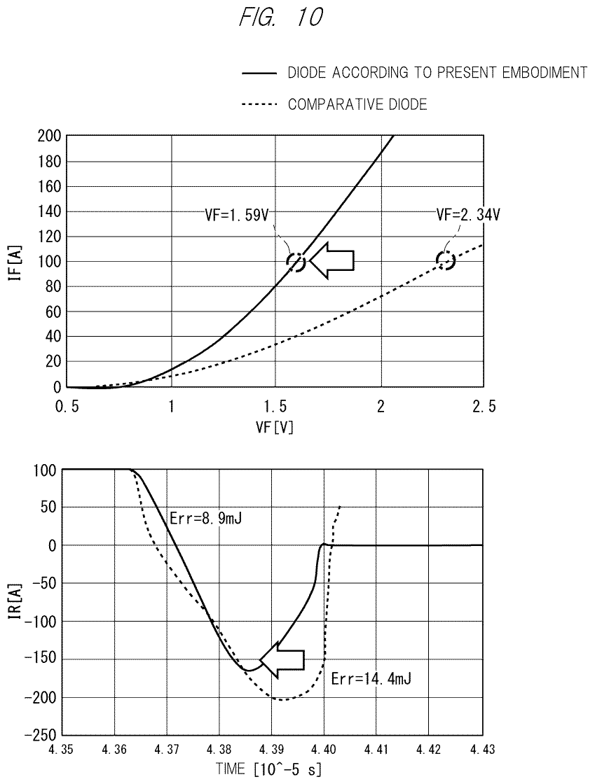

Next, simulation results of the VF-IF curves and recovery waveforms of the diode according to the present embodiment and the comparison diode are illustrated in FIG. 10. For the comparison diode, the same simulation results as those in the first embodiment are used.

First, simulation results of the VF-IF curves illustrated in the upper graph in FIG. 10 will be described. When the IF is 100 A, the VF is 1.59 V in the diode according to the present embodiment and 2.34 V in the comparative diode, and thus the VF is reduced by about 32.1%. This shows that the diode according to the present embodiment has an effect of reducing the VF.

Next, simulation results of the recovery waveforms illustrated in the lower graph in FIG. 10 will be described. The lower graph in FIG. 10 is a graph in which the horizontal axis represents recovery time and the vertical axis represents a reverse current. The recovery loss (Err) calculated from these simulation results is 8.9 mJ in the diode according to the present embodiment and 14.4 mJ in the comparative diode, and thus the Err is reduced by about 38.2%. This shows that the diode according to the present embodiment has an effect of reducing the Err.

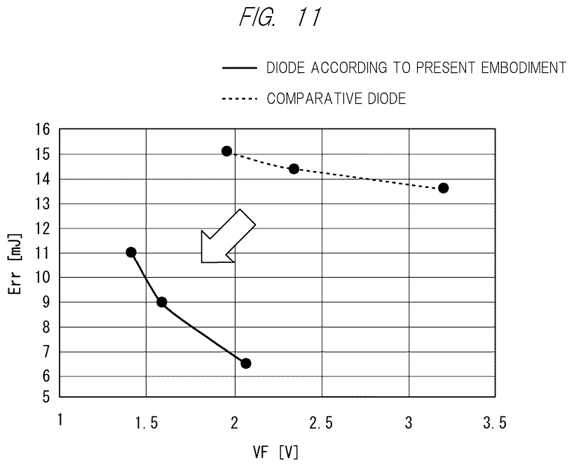

FIG. 11 is a graph in which the horizontal axis is the VF and the vertical axis is the Err on the basis of the simulation results of the diode according to the present embodiment and the comparison diode, that is, illustrates trade-off curves. Since the diode according to the present embodiment has an effect of reducing the VF and the Err, it can be seen that the trade-off curve is greatly improved as compared with that of the comparative diode.

In this manner, it is possible to provide a semiconductor device including an RC-IGBT capable of reducing VF and Err of a diode.

### Fourth Embodiment

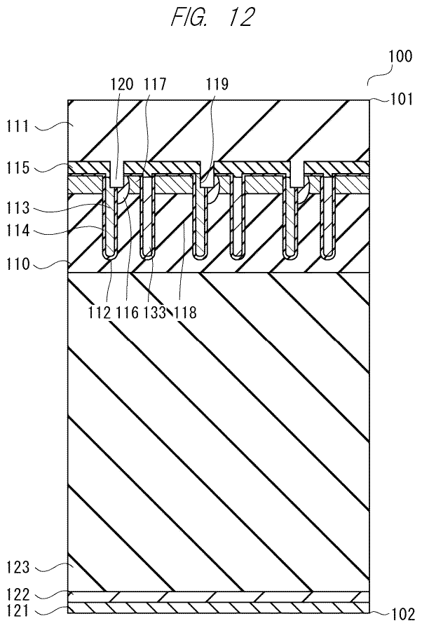

In the present embodiment, a semiconductor device obtained by advancing the first to third embodiments will be described. FIG. 12 illustrates a region where a diode (FWD) is formed in a semiconductor substrate included in a semiconductor device according to the present embodiment. In the diode according to the present embodiment, similarly to the third embodiment, the anode layer 110 is formed up to a region deeper than the trench 112, has the region 118 where the contact hole 120 is not formed, and has the share contact portion 140. Note that, although the broken line portion indicating the share contact portion 140 is omitted in FIG. 12 due to limitations of space of the drawing, the share contact portion 140 is formed in the vicinity of the region 119 as in the third embodiment.

The diode according to the present embodiment includes an electrically independent control trench electrode 133. As a result, while the semiconductor device has performance of reducing the VF and the Err of the diode similarly to the diode according to the first to third embodiments, the semiconductor device can perform four-terminal control.

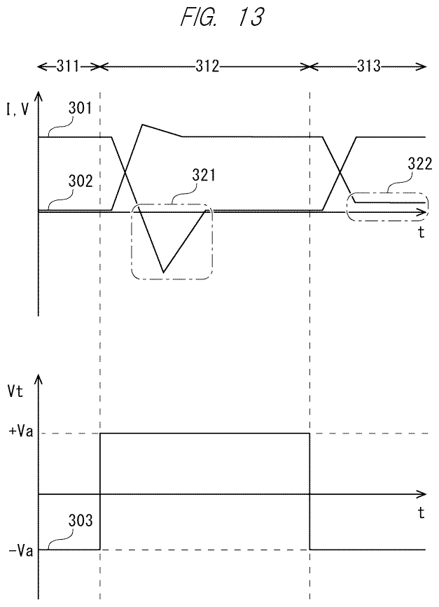

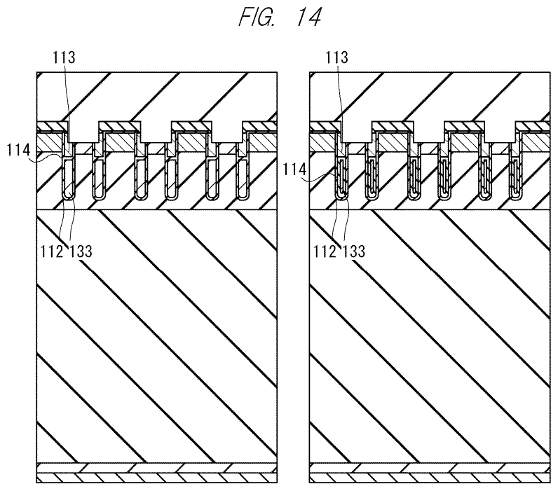

The operation of the RC-IGBT including the control trench electrode 133 will be described with reference to FIG. 13. The upper graph in FIG. 13 represents temporal changes when the vertical axis represents a current I and a voltage V, and the lower graph in FIG. 13 represents temporal changes when the vertical axis represents a potential Vt of the control trench electrode 133. A plotted line of the current I is illustrated as a line 301, a plotted line of the voltage V is illustrated as a line 302, and a plotted line of the potential Vt of the control trench electrode 133 is illustrated as a line 303.

When a conduction period 311 changes to an off period 312, a recovery loss (Err) 321 occurs in the current I. In order to reduce this recovery loss, a negative potential −Va is applied by the control trench electrode 133 in the conduction period 311, and a positive potential +Va is applied by the control trench electrode 133 in the off period 312. By operating in this manner, recovery can be speeded up.

In addition, when the off period 312 changes to a conduction period 313, a conduction loss (VF) 322 occurs in the voltage V. In order to reduce this conduction loss, a potential applied by the control trench electrode 133 changes from +Va to −Va when the off period 312 changes to the conduction period 313. By operating in this manner, the conduction loss can be reduced.

By performing the four-terminal control as described above, it is possible to provide a semiconductor device including an RC-IGBT capable of reducing VF and Err of a diode.

### Fifth Embodiment

In the present embodiment, a semiconductor device obtained by advancing the fourth embodiment will be described. FIG. 14 illustrates a region where a diode (FWD) is formed in a semiconductor substrate included in a semiconductor device according to the present embodiment. The diode according to the present embodiment has a structure in which the control trench electrode 133 is provided inside the trench 112.

The left diagram in FIG. 14 illustrates a structure in which the control trench electrode 133 is provided below the trench electrode 113 with the trench oxide film 114 interposed therebetween inside the trench 112. The right diagram in FIG. 14 is the same as the left diagram in FIG. 14 in that the control trench electrode 133 is provided below the trench electrode 113, but is different in that the control trench electrode 133 is provided in the trench oxide film 114.

With such a configuration, the four-terminal control can be performed in all trenches, so that it is possible to provide a semiconductor device including an RC-IGBT capable of reducing VF and Err of a diode.

### Sixth Embodiment

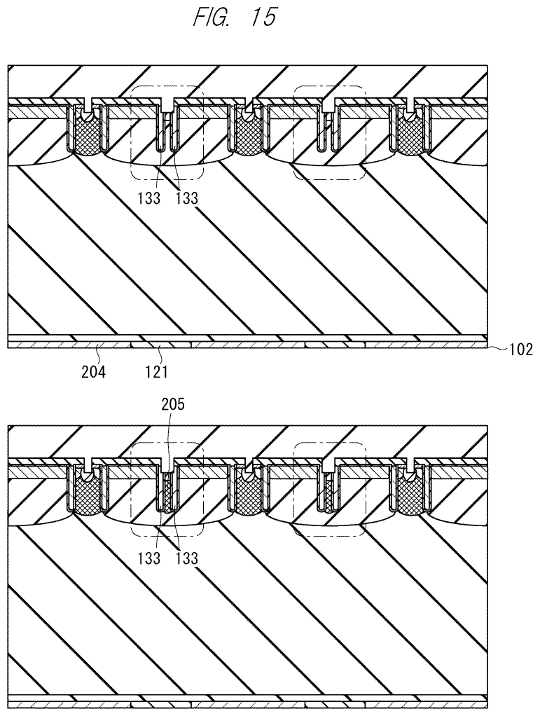

Unlike the first to fifth embodiments, the present embodiment describes a semiconductor device in which an IGBT and a diode are provided in different regions. FIG. 15 illustrates a semiconductor substrate included in the semiconductor device according to the present embodiment. In FIG. 15, a region circled by the broken line is a region where the diode is formed, and the IGBT and the diode are alternately formed. On the second surface 102, the cathode layer 121 and a collector layer 204 are formed.

In the upper diagram in FIG. 15, the control trench electrode 133 is formed in the trench in the region where the diode is formed. The potential of the control trench electrode 133 may be fixed to be the same potential as the emitter potential, or an independent voltage may be applied to the control trench electrode 133. In the latter case, the four-terminal control can be performed as in the fifth embodiment.

As illustrated in the lower diagram in FIG. 15, a high-concentration n+ layer 205 may be formed between the two control trench electrodes 133. By forming the n+ layer 205, the potential of the trench can be controlled using the floating region of the IGBT. When the IGBT is turned on to be in a conductive state, a positive potential is applied to the control trench electrode 133, discharge of holes from the n+ layer 205 is suppressed, and an injection enhancement effect (IE effect) of the IGBT is improved. When the IGBT is turned off, a negative potential is applied to the control trench electrode 133, and the n+ layer 205 forms a p inversion layer. As a result, since the discharge of holes from the p inversion layer increases, the turn-off of the IGBT becomes fast. By forming the p inversion layer, the floating layer functions as an anode layer.

With such a configuration, it is possible to provide a semiconductor device including an RC-IGBT capable of reducing VF and Err of a diode.

Although the invention made by the present inventors has been specifically described based on the embodiments, the present invention is not limited to the embodiments described above, and it goes without saying that various modifications can be made without departing from the gist of the present invention.

What is claimed is:

1. A semiconductor device comprising:
a semiconductor substrate having a first surface and a second surface opposite to the first surface; and
a diode formed in the semiconductor substrate,
wherein the diode includes a drift layer of a first conductivity type on a side provided with the first surface, an anode layer of a second conductivity type opposite in conductivity type to the first conductivity type on the drift layer, and a trench, and
wherein a bottom surface of the anode layer is located in a region deeper than a bottom surface of the trench with reference to the first surface.

2. The semiconductor device according to claim 1,
wherein a pn junction portion is formed between the drift layer and the anode layer, and
wherein the trench has a structure of not penetrating the pn junction portion.

3. The semiconductor device according to claim 2,
wherein a lifetime killer is introduced into the pn junction portion.

4. The semiconductor device according to claim 1,
wherein the diode further includes:
a second trench adjacent to the trench; and
a body layer of the second conductivity type between the trench and the second trench in a cross-sectional view of the semiconductor substrate, and
wherein the body layer is connected to an anode electrode of the diode via a contact hole.

5. The semiconductor device according to claim 4,
wherein the anode layer has a function of accumulating carriers in a region where the contact hole is not formed.

6. The semiconductor device according to claim 4,
wherein the contact hole has a region overlapping with the trench and the second trench, and
wherein trench electrodes of the trench and the second trench are connected to the anode electrode via the contact hole.

7. A semiconductor device comprising:
a semiconductor substrate having a first surface and a second surface opposite to the first surface; and
a diode formed in the semiconductor substrate,
wherein the diode includes a drift layer of a first conductivity type on a side provided with the first surface, an anode layer of a second conductivity type opposite in conductivity type to the first conductivity type on the drift layer, and a first trench and a second trench,
wherein a bottom surface of the anode layer is located in a region deeper than a bottom surface of the first trench with reference to the first surface, and
wherein an independent voltage from a voltage applied to a trench electrode of the first trench is applied to a trench electrode of the second trench.

8. The semiconductor device according to claim 7,
wherein a pn junction portion is formed between the drift layer and the anode layer, and
wherein the first trench has a structure of not penetrating the pn junction portion.

9. The semiconductor device according to claim 8,
wherein a lifetime killer is introduced into the pn junction portion.

10. The semiconductor device according to claim 7,
wherein the diode further includes a body layer of the second conductivity type between the first trench and the second trench in a cross-sectional view of the semiconductor substrate, and
wherein the body layer and a trench electrode of the first trench are connected to an anode electrode of the diode via a contact hole.

11. The semiconductor device according to claim 10,
wherein the anode layer has a function of accumulating carriers in a region where the contact hole is not formed.

12. A semiconductor device comprising:
a semiconductor substrate having a first surface and a second surface opposite to the first surface; and
an insulated gate bipolar transistor (IGBT) and a diode formed in the semiconductor substrate,
wherein the diode includes a drift layer of a first conductivity type on a side provided with the first surface, an anode layer of a second conductivity type opposite in conductivity type to the first conductivity type on the drift layer, and a first trench and a second trench,
wherein a bottom surface of the anode layer is located in a region deeper than a bottom surface of the first trench with reference to the first surface,
wherein an independent voltage from a voltage applied to a trench electrode of the first trench is applied to a trench electrode of the second trench, and
wherein a layer of the first conductivity type is provided between the first trench and the second trench.

13. The semiconductor device according to claim 1,
wherein the semiconductor substrate further includes an insulated gate bipolar transistor (IGBT) , and
wherein a reverse-conducting IGBT is formed by the IGBT and the diode.

14. The semiconductor device according to claim 7,
wherein the semiconductor substrate further includes an insulated gate bipolar transistor (IGBT), and
wherein a reverse-conducting IGBT is formed by the IGBT and the diode.

15. The semiconductor device according to claim 12,
wherein the semiconductor substrate has an active region in which the IGBT and the diode are formed and a peripheral region in which the IGBT and the diode are not formed, and
wherein a thickness of the anode layer in the peripheral region is equal to or smaller than a thickness of the anode layer in the active region.

16. The semiconductor device according to claim 13,
wherein the semiconductor substrate has an active region in which the IGBT and the diode are formed and a peripheral region in which the IGBT and the diode are not formed, and
wherein a thickness of the anode layer in the peripheral region is equal to or smaller than a thickness of the anode layer in the active region.

17. The semiconductor device according to claim 14,
wherein the semiconductor substrate has an active region in which the IGBT and the diode are formed and a peripheral region in which the IGBT and the diode are not formed, and
wherein a thickness of the anode layer in the peripheral region is equal to or smaller than a thickness of the anode layer in the active region.
